(19) United States
(12) Patent Application Publication
(10) Pub. No.: US 2024/0203811 A1
(43) Pub. Date: Jun. 20, 2024

(54) SEMICONDUCTOR DEVICE

(71) Applicant: DENSO CORPORATION, Kariya-city, Aichi-pref. (JP)

(72) Inventors: NOBUYUKI KATO, Kariya-city (JP); YUTAKA TOMATSU, Kariya-city (JP)

(21) Appl. No.: 18/420,125

(22) Filed: Jan. 23, 2024

Related U.S. Application Data
(63) Continuation of application No. PCT/JP2022/032778, filed on Aug. 31, 2022.

(30) Foreign Application Priority Data
Sep. 3, 2021 (JP) 2021-143928

(51) Int. Cl. H01L 23/31; H01L 21/04; H01L 23/495; H01L 29/06; H01L 29/16; H01L 29/66; H01L 29/78

(52) U.S. Cl. CPC H01L 23/3142; H01L 21/046; H01L 23/4952; H01L 23/49562; H01L 23/49568; H01L 29/0623; H01L 29/063; H01L 29/1608; H01L 29/66068; H01L 29/7811; H01L 29/7813

(57) ABSTRACT

A semiconductor device includes a support member, a semiconductor chip and a mold resin sealing the support member and the semiconductor chip. The semiconductor chip includes a semiconductor substrate having a first surface and a second surface opposite to the first surface and formed with a semiconductor element. The semiconductor chip is disposed on the support member such that the second surface of the semiconductor substrate faces the support member. The semiconductor chip has a cell region in which the semiconductor element is disposed and an outer peripheral region surrounding the cell region. The semiconductor chip has a protective film disposed in the outer peripheral region on a side adjacent to the first surface of the semiconductor substrate. A surface of the protective film opposite to the semiconductor substrate has a surface roughness of 5 nm or more, and includes an uneven structure.

### CROSS REFERENCE TO RELATED APPLICATIONS

The present application is a continuation application of International Patent Application No. PCT/JP2022/032778 filed on Aug. 31, 2022, which designated the U.S. and claims the benefit of priority from Japanese Patent Application No. 2021-143928 filed on Sep. 3, 2021. The entire disclosures of all of the above applications are incorporated herein by reference.

### TECHNICAL FIELD

The present disclosure relates to a semiconductor device in which a semiconductor chip is sealed with a mold resin.

### BACKGROUND

Conventionally, a semiconductor device in which a semiconductor chip is sealed with a mold resin has been proposed. Specifically, in such a semiconductor device, a semiconductor chip is disposed on a support member, and a mold resin is disposed so as to seal the support member and the semiconductor chip. The semiconductor chip includes a cell region and an outer peripheral region surrounding the cell region. In the cell region, for example, a metal oxide semiconductor field effect transistor (MOSFET) element or the like is formed. Further, the support member is formed with a groove, so that the mold resin can enter the groove, thereby to restrict separation of the mold resin from the support member.

### SUMMARY

The present disclosure describes a semiconductor device including a support member, a semiconductor chip and a mold resin sealing the support member and the semiconductor chip. According to an aspect of the present disclosure, in the semiconductor device, the semiconductor chip includes a semiconductor substrate having a first surface and a second surface opposite to the first surface and formed with a semiconductor element. The semiconductor chip is disposed on the support member such that the second surface of the semiconductor substrate faces the support member. The semiconductor chip has a cell region in which the semiconductor element is disposed and an outer peripheral region surrounding the cell region. The semiconductor chip has a protective film disposed in the outer peripheral region on a side adjacent to the first surface of the semiconductor substrate. A surface of the protective film opposite to the semiconductor substrate has a surface roughness of 5 nm or more, and includes an uneven structure.

### BRIEF DESCRIPTION OF DRAWINGS

Features and advantages of the present disclosure will become more apparent from the following detailed description made with reference to the accompanying drawings, in which:

FIG. 1 is a cross-sectional view of a semiconductor device according to a first embodiment;

FIG. 2 is a plan view of a semiconductor chip shown in FIG. 1;

FIG. 3 is a cross-sectional view taken along a line III-III in FIG. 2;

FIG. 4 is a diagram showing a relationship between a surface roughness of a protective film and an adhering strength of the protective film;

FIG. 5A is a cross-sectional view showing a manufacturing process of a semiconductor chip;

FIG. 5B is a cross-sectional view showing a manufacturing process of the semiconductor chip subsequent to FIG. 5A;

FIG. 5C is a cross-sectional view showing a manufacturing process of the semiconductor chip subsequent to FIG. 5B;

FIG. 5D is a cross-sectional view showing a manufacturing process of the semiconductor chip subsequent to FIG. 5C;

FIG. 5E is a cross-sectional view showing a manufacturing process of the semiconductor chip subsequent to FIG. 5D;

FIG. 5F is a cross-sectional view showing a manufacturing process of the semiconductor chip subsequent to FIG. 5E;

FIG. 5G is a cross-sectional view showing a manufacturing process of the semiconductor chip subsequent to FIG. 5F;

FIG. 5H is a cross-sectional view showing a manufacturing process of the semiconductor chip subsequent to FIG. 5G;

FIG. 6 is a cross-sectional view of a semiconductor chip according to a second embodiment;

FIG. 7A is a cross-sectional view showing a manufacturing process of a semiconductor chip according to the second embodiment;

FIG. 7B is a cross-sectional view showing a manufacturing process of the semiconductor chip subsequent to FIG. 7A;

FIG. 7C is a cross-sectional view showing a manufacturing process of the semiconductor chip subsequent to FIG. 7B;

FIG. 7D is a cross-sectional view showing a manufacturing process of the semiconductor chip subsequent to FIG. 7C;

FIG. 7E is a cross-sectional view showing a manufacturing process of the semiconductor chip subsequent to FIG. 7D;

FIG. 7F is a cross-sectional view showing a manufacturing process of the semiconductor chip subsequent to FIG. 7E;

FIG. 7G is a cross-sectional view showing a manufacturing process of the semiconductor chip subsequent to FIG. 7F;

FIG. 7H is a cross-sectional view showing a manufacturing process of the semiconductor chip subsequent to FIG. 7G;

FIG. 8 is a cross-sectional view of a semiconductor chip according to a third embodiment;

FIG. 9A is a cross-sectional view showing a manufacturing process of a semiconductor chip according to the third embodiment;

FIG. 9B is a cross-sectional view showing a manufacturing process of the semiconductor chip subsequent to FIG. 9A;

FIG. 9C is a cross-sectional view showing a manufacturing process of the semiconductor chip subsequent to FIG. 9B;

FIG. 9D is a cross-sectional view showing a manufacturing process of the semiconductor chip subsequent to FIG. 9C;

FIG. 9E is a cross-sectional view showing a manufacturing process of the semiconductor chip subsequent to FIG. 9D;

FIG. 10 is a cross-sectional view of a semiconductor chip according to a fourth embodiment;

FIG. 11A is a cross-sectional view showing a manufacturing process of the semiconductor chip according to the fourth embodiment;

FIG. 11B is a cross-sectional view showing a manufacturing process of the semiconductor chip subsequent to FIG. 11A;

FIG. 12 is a cross-sectional view of a semiconductor chip according to a fifth embodiment;

FIG. 13 is a cross-sectional view of a semiconductor chip according to a sixth embodiment;

FIG. 14 is a cross-sectional view of a semiconductor chip according to a seventh embodiment;

FIG. 15 is a cross-sectional view of a semiconductor chip according to an eighth embodiment;

FIG. 16 is a cross-sectional view of a semiconductor chip according to a ninth embodiment;

FIG. 17 is a cross-sectional view of a semiconductor device according to another embodiment; and

FIG. 18 is a cross-sectional view of a semiconductor device according to a further another embodiment.

### DETAILED DESCRIPTION

For example, there has been known a semiconductor device in which a semiconductor chip is disposed on a support member, and sealed with a mold resin together with the support member. In such a semiconductor device, the support member may be formed with a groove to receive the mold resin therein, thereby to restrict separation of the mold resin from the support member.

The inventors of the present disclosure have studied the semiconductor device in which the semiconductor chip is sealed with the mold resin as described above, and have confirmed that there is a possibility that the mold resin is also separated from an outer edge portion of the semiconductor chip. Further, if the separation progresses toward an inner portion of the semiconductor chip, there is a possibility that the withstand voltage of the semiconductor element changes, or a wire connected to the semiconductor chip is disconnected.

The present disclosure provides a semiconductor device capable of suppressing separation between a mold resin and a semiconductor chip from reaching an inner edge portion of a semiconductor chip.

According to an aspect of the present disclosure, a semiconductor device includes: a support member having one surface; a semiconductor chip including a semiconductor substrate having a first surface and a second surface and formed with a semiconductor element, the semiconductor chip being disposed on the support member in a state where the second surface of the semiconductor substrate faces the support member; and a mold resin sealing the support member and the semiconductor chip. The semiconductor chip has a cell region in which the semiconductor element is disposed and an outer peripheral region surrounding the cell region. The semiconductor chip includes a protective film disposed in the outer peripheral region on the first surface side of the semiconductor substrate. The protective film has a surface roughness of 5 nm or more on a surface opposite to the semiconductor substrate and includes an uneven structure in the surface.

According to such a configuration, the protective film has the surface roughness of 5 nm or more. Therefore, it is possible to suppress a decrease in adhesion strength between the protective film and the mold resin. As a result, it is possible to suppress separation of the mold resin from the semiconductor chip.

In addition, the protective film has the uneven structure on the surface opposite to the semiconductor substrate. Therefore, when the mold resin is separated from the outer edge portion of the semiconductor chip, the extension direction of the separation can be changed by the uneven structure, and the stress for extending the separation can be reduced. As such, it is possible to suppress the separation from reaching an inner edge portion of the semiconductor chip.

Embodiments of the present disclosure will be described hereinafter with reference to the drawings. In the following description, the same or equivalent parts are denoted by the same reference numerals throughout the embodiments.

### First Embodiment

A first embodiment will be described with reference to the drawings. A semiconductor device of the present embodiment is preferably mounted on a vehicle such as an automobile and applied as a device for driving various electronic devices for the vehicle.

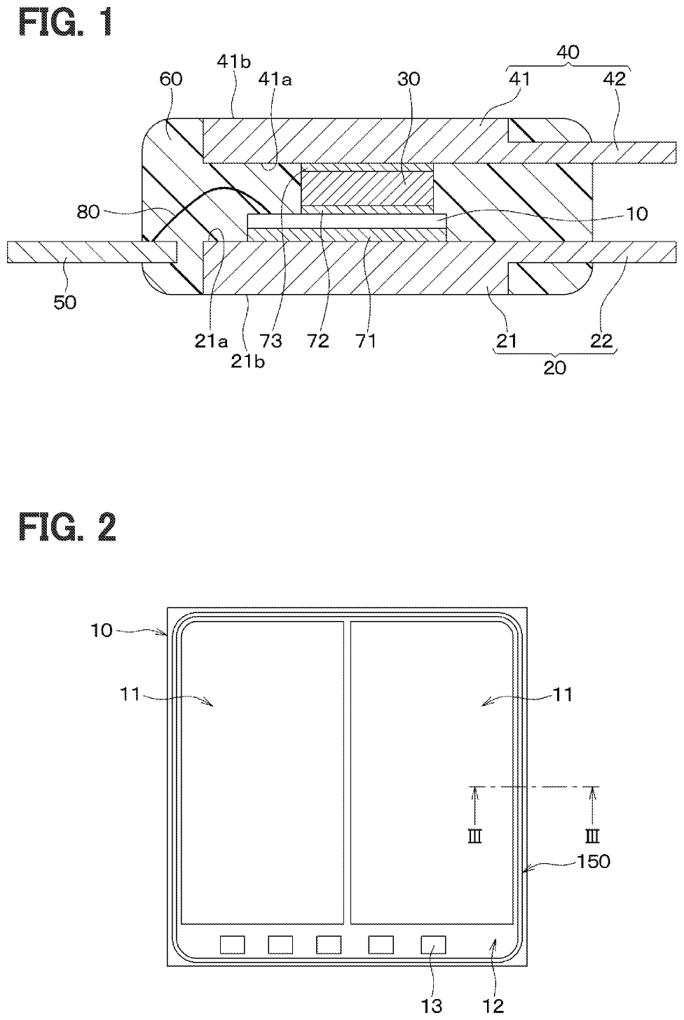

As shown in FIG. 1, the semiconductor device of the present embodiment includes a semiconductor chip 10, a first lead frame 20, a block body 30, a second lead frame 40, a control terminal portion 50, and the like. The semiconductor device also includes a mold resin 60 that integrally seals these components. In the present embodiment, the first lead frame 20 corresponds to a support member.

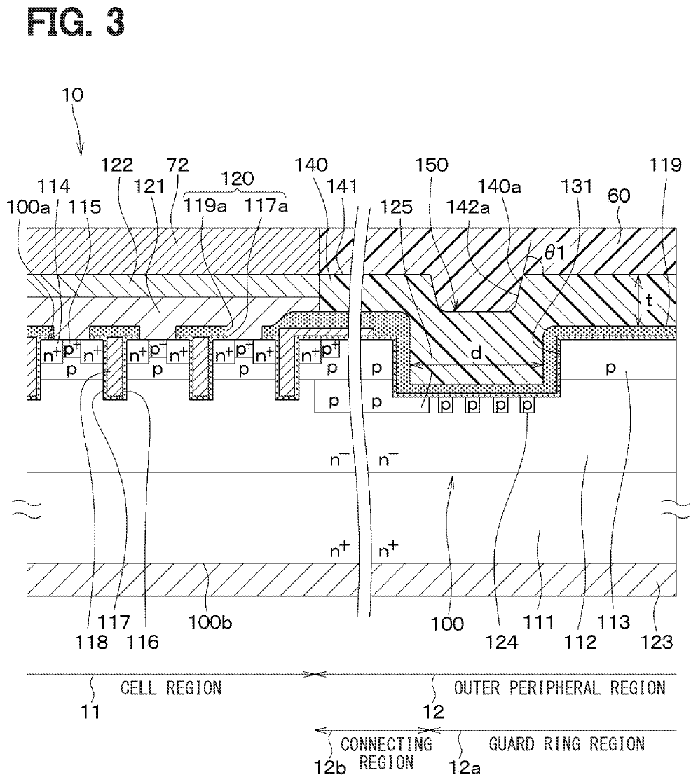

As shown in FIG. 2, the semiconductor chip 10 includes a cell region 11 and an outer peripheral region 12, and a specific configuration of the semiconductor chip 10 will be described later. As shown in FIG. 3, the cell region 11 is formed with a MOSFET element having a gate electrode 118, a source electrode 121, a drain electrode 123, and the like. As shown in FIG. 2, the outer peripheral region 12 is formed with a pad portion 13 connected to a gate electrode 118 and the like.

The first lead frame 20 is made of a highly conductive material such as copper or 42-alloy, and has a shape in which a mounting portion 21 and a main terminal portion 22 are integrally formed. In the first lead frame 20, the semiconductor chip 10 is mounted on one surface 21a of the mounting portion 21 via a bonding member 71 such as solder. Alternatively, the mounting portion 21 and the main terminal portion 22 may be provided by separate members.

The block body 30 is made of a conductive material such as copper or aluminum and has a rectangular parallelepiped shape. The block body 30 is disposed on the source electrode 121 of the semiconductor chip 10 via a bonding member 72 such as solder.

Similarly to the first lead frame 20, the second lead frame 40 is made of a highly conductive material such as copper or 42-alloy, and has a shape in which a mounting portion 41 and a main terminal portion 42 are integrally formed. The second lead frame 40 is disposed such that one surface 41a of the mounting portion 41 is connected to a bonding member 73, such as solder, disposed on the block body 30. Alternatively, the mounting portion 41 and the main terminal portion 42 may be provided by separate members.

The control terminal portion 50 is disposed in the vicinity of the semiconductor chip 10. The control terminal portion 50 is electrically connected to the pad portion 13 formed in the semiconductor chip 10 via the wire 80.

The mold resin 60 is made of a resin material such as epoxy resin. The mold resin 60 is disposed such that the other surface 21b of the first lead frame 20 opposite to the one surface 21a of the mounting portion 21 and the other surface 41b of the second lead frame 40 opposite to the one surface 41a of the mounting portion 41 are exposed from the mold resin 60. Further, the mold resin 60 is disposed such that the main terminal portions 22 and 42 and the control terminal portions 50 are partially exposed. Accordingly, the semiconductor device of the present embodiment is a semiconductor device having a so-called double-sided heat dissipation structure. In order to adjust the thermal expansion coefficient, an additive (not shown) such as silica may be mixed in the mold resin 60.

The general configuration of the semiconductor device according to the present embodiment is described hereinabove. Next, the configuration of the semiconductor chip 10 of the present embodiment will be specifically described with reference to FIGS. 2 and 3. Note that FIG. 3 shows a cross-sectional view of the semiconductor chip 10 taken along a line III-III in FIG. 2, and the bonding member 72 and the mold resin 60 are partially shown in order to facilitate understanding of the positional relationship. Similarly, in the drawings each corresponding to FIG. 3 described later, the bonding member 72 and the mold resin 60 are partially shown in order to facilitate understanding of the positional relationship.

As shown in FIG. 2, the semiconductor chip 10 has a planar shape having corner portions, and has a rectangular plate shape in the present embodiment. As shown in FIG. 3, a MOSFET element having a trench gate structure is formed as a semiconductor element in the cell region 11 of the semiconductor chip 10. The outer peripheral region 12 of the present embodiment includes a guard ring region 12a and a connection region 12b disposed inside the guard ring region 12a. In other words, the outer peripheral region 12 includes the guard ring region 12a and the connection region 12b disposed between the cell region 11 and the guard ring region 12a.

In the present embodiment, the semiconductor chip 10 is configured using a silicon carbide (hereinafter also referred to as SiC) substrate as the semiconductor substrate 100. However, the semiconductor substrate 100 may be configured using a silicon substrate or a gallium nitride substrate instead of the SiC substrate.

The semiconductor substrate 100 of the present embodiment has an n⁺-type substrate 111 constituting a high-concentration impurity layer made of SiC. The substrate 111 constitutes a drain region in the MOSFET element. An n⁻-type drift layer 112 made of SiC having an impurity concentration lower than that of the substrate 111 is epitaxially grown on the substrate 111. A p-type base region 113 is epitaxially grown on the drift layer 112. In the present embodiment, the base region 113 is formed over the cell region 11 and the outer peripheral region 12. An n⁺-type source region 114 is formed in a surface layer portion of the base region 113 of the cell region 11. Hereinafter, a surface of the semiconductor substrate 100 adjacent to the base region 113 will be referred to as the one surface 100a of the semiconductor substrate 100, and a surface of the semiconductor substrate 100 adjacent to the substrate 111 will be referred to as the other surface 100b of the semiconductor substrate 100. The one surface 100a will be also referred to as a first surface 100a of the semiconductor substrate 100, and the other surface 100b will be also referred to as a second surface 100b of the semiconductor substrate 100.

The substrate 111 has, for example, an n-type impurity concentration of 1.0×10¹⁹/cm³ and a surface of a (0001) Si plane. The drift layer 112 has an impurity concentration lower than that of the substrate 111. For example, the drift layer 112 has an n-type impurity concentration of 0.5×10¹⁶ to 2.0×10¹⁶/cm³.

The base region 113 is a part in which a channel region is formed, and is configured to have, for example, a p-type impurity concentration of about 2.0×10¹⁷/cm³ and a thickness of 300 nm. The source region 114 has an impurity concentration higher than that of the drift layer 112, and is configured to have, for example, an n-type impurity concentration of 2.5×10¹⁸ to 1.0×10¹⁹/cm³ in a surface layer portion and a thickness of about 0.5 μm.

In the cell region 11, a contact region 115 is formed in a surface layer portion of the base region 113. The contact region 115 is formed of a p-type high-concentration layer. Specifically, the contact region 115 is formed opposite to a trench 116, which will be described later, with respect to the source region 114.

In the cell region 11, the trench 116, which for example has a width of 0.8 μm and a depth of 1.0 μm, is formed so as to penetrate the base region 113 and the source region 114 from the one surface 100a side of the semiconductor substrate 100 and to reach the drift layer 112. In other words, the base region 113 and the source region 114 are arranged so as to adjoin with the side surface of the trench 116. The trench 16 has a width along a horizontal direction in FIG. 3, and a depth along a vertical direction in FIG. 3. Also, the trench 16 has a longitudinal direction along a direction normal to a paper surface in FIG. 3. In the present embodiment, multiple trenches 116 are formed in parallel to each other and at equal intervals. That is, the trench 116 of the present embodiment is provided to extend in a direction intersecting with a stacking direction of the drift layer 112 and the base region 113 (hereinafter, also simply referred to as a stacking direction), specifically, in a direction orthogonal to the stacking direction. In other words, the trenches 116 extend along one direction along a planar direction of the substrate 111. Further, the trenches 116 are drawn around at distal end portion thereof in the extending direction so as to have an annular structure. Alternatively, the trenches 116 may be formed in a stripe shape in which the multiple trenches 116 are formed in parallel at equal intervals.

The trench 116 is filled with a gate insulating film 117 and a gate electrode 118. Specifically, assuming that a portion of the base region 113 located on the side surface of the trench 116 is a channel region connecting the source region 114 and the drift layer 112 during operation of the MOSFET element, the gate insulating film 117 is formed on the inner wall surface of the trench 116 including the channel region. The gate insulating film 117 is, for example, provided by a thermal oxide film or the like. The gate electrode 118 is made of doped polysilicon, and is formed on the surface of the gate insulating film 117.

The gate insulating film 117 is also formed on surfaces other than the inner wall surface of the trench 116. Specifically, the gate insulating film 117 is formed so as to also cover a part of the one surface 100a of the semiconductor substrate 100. More specifically, the gate insulating film 117 is also formed to cover a part of the surface of the source region 114. The gate insulating film 117 is formed with a contact hole 117a at a portion different from the portion where the gate electrode 118 is disposed. The contact hole 117a exposes the contact region 115 and the rest portion of the source region 114.

The gate insulating film 117 is formed also on the surface of the base region 113 and the like in the outer peripheral region 12. The gate insulating film 117 is formed also on the surface of a depressed portion 131, which will be described later. The gate electrode 118 extends over the surface of the gate insulating film 117 in the connection region 12b of the outer peripheral region 12. The trench gate structure of the present embodiment has the configuration as described hereinabove.

An interlayer insulating film 119 is formed on the one surface 100a of the semiconductor substrate 100 so as to cover the gate electrode 118, the gate insulating film 117, and the like. The interlayer insulating film 119 is made of borophosphosilicate glass (BPSG) or the like.

The interlayer insulating film 119 is formed with a contact hole 119a that is communicated with the contact hole 117a and exposes the source region 114 and the contact region 115. In a cross section different from FIG. 3, the interlayer insulating film 119 is further formed with a contact hole that exposes a portion of the gate electrode 118 extended over the connection region 12b.

The contact hole 119a of the interlayer insulating film 119 is formed so as to communicate with the contact hole 117a of the gate insulating film 117, and thus functions as one contact hole together with the contact hole 117a. Therefore, in the following description, the contact hole 117a and the contact hole 119a are collectively referred to as a contact hole 120. In addition, the pattern of the contact hole 120 is arbitrary. Example of the pattern of the contact hole 120 may include a pattern in which multiple square holes are arranged, a pattern in which rectangular line-shaped holes are arranged, a pattern in which line-shaped holes are arranged, or the like. In the present embodiment, the contact hole 120 is designed to have a linear shape along the longitudinal direction of the trench 116.

A source electrode 121 is disposed above the interlayer insulating film 119. The source electrode 121 is electrically connected to the source region 114 and the contact region 115 through the contact hole 120. Also, a gate wiring is disposed above the interlayer insulating film 119 in a cross section different from FIG. 3. The gate wiring is electrically connected to the gate electrode 118 through a contact hole that is formed to expose the gate electrode 118. The gate wiring is appropriately routed and electrically connected to one of the pad portions 13 shown in FIG. 2. The source electrode 121 is disposed in the entire cell region 11 and has an area sufficiently larger than that of the pad portion 13.

The source electrode 121 and the gate wiring are formed of, for example, Al—Si layers or the like. However, the material forming the source electrode 121 and the gate wiring is not limited thereto, and may be formed only of Al or may be formed of another material containing Al as a main component. In the present embodiment, the source electrode 121 is disposed up to the boundary portion between the cell region 11 and the outer peripheral region 12.

A plating layer 122 is disposed above the source electrode 121 for improving solder wettability when being connected to an external member. For example, the plating layer 122 is formed by a stack of a nickel plating layer and a gold plating layer in which the nickel plating layer is adjacent to the source electrode 121.

A drain electrode 123 is disposed on the rear surface of the substrate 111, that is, on the other surface 100b of the semiconductor substrate 111. The drain electrode 123 is electrically connected to the substrate 111. The drain electrode 123 corresponds to a second electrode. The configuration described hereinabove forms an n-channel type MOSFET element having an inverted trench gate structure.

The semiconductor chip 10 is appropriately formed with a current sensing element, a temperature sensing element, and the like, although not described in detail. These sensing elements are electrically connected to the pad portions 13 shown in FIG. 1 as appropriate.

Further, the outer peripheral region 12 is formed with a depressed portion 131 that is depressed from the one surface 100a of the semiconductor substrate 100 and reaches the drift layer 112. In the present embodiment, the depressed portion 131 is disposed in an area extending from the connection region 12b to the guard ring region 12a, and has the same depth as the trench 116. In addition, the depressed portion 131 of the present embodiment is partially depressed so as to have opposing side surfaces. That is, the depressed portion 131 of the present embodiment is formed inside the outer peripheral region 12, and is not formed so as to reach the outer edge portion of the semiconductor chip 10.

In the guard ring region 12a, multiple p-type guard rings 124 are provided in a surface layer portion of the drift layer 112 located below the depressed portion 131. The p-type guard rings 124 are disposed so as to surround the cell region 11. In the present embodiment, the layout of the guard ring 124, when viewed from the top or viewed along the stacking direction, has a rectangular shape with four rounded corners, a circular shape, or the like.

The guard ring 124 of the present embodiment is formed by, for example, ion implantation as described later. Viewing along the stacking direction is, in other words, viewing along the normal direction with respect to the planar direction of the substrate 111. Although not illustrated, the guard ring region 12a may include an equipotential ring (EQR) structure or the like on the outer periphery of the guard ring 124, as necessary.

In the connection region 12b, a p-type RESURF layer 125 is disposed in a surface layer portion of the drift layer 112. For example, the RESURF layer 125 has a shape that extends to the guard ring region 12a while surrounding the cell region 11, when viewed along the stacking direction. Therefore, the equipotential lines can be guided toward the guard ring region 12a, and the occurrence of electric field concentration in the connection region 12b can be suppressed. As such, a decrease in withstand voltage can be suppressed.

As described above, the gate insulating film 117 and the interlayer insulating film 119 are extended also over the outer peripheral region 12, and are formed along the wall surface of the depressed portion 131 in the area where the depressed portion 131 is formed. However, the gate insulating film 117 and the interlayer insulating film 119 are formed so as not to fill the depressed portion 131.

A protective film 140 is disposed above the one surface 100a of the semiconductor substrate 100 so as to expose the plating layer 122. In other words, the protective film 140 is disposed in the connection region 12b and the guard ring region 12a above the one surface 100a of the semiconductor substrate 100. The protective film 140 is made of polyimide, a nitride film, or the like.

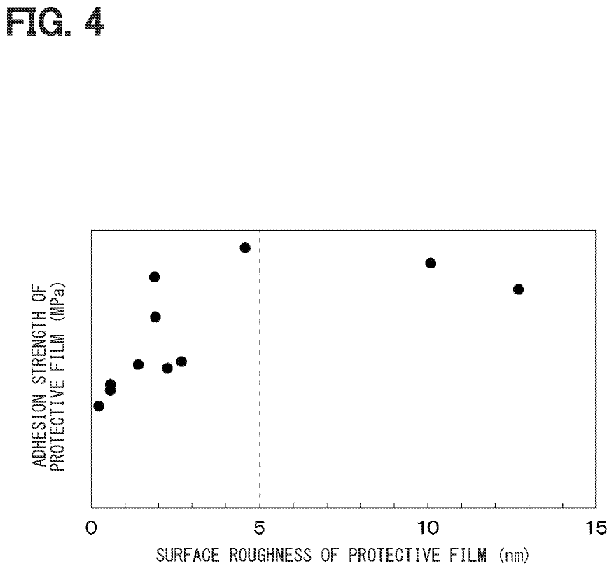

In the present embodiment, the surface of the protective film 140 opposite to the semiconductor substrate 100 is referred to as a main face 141. The main face 141 of the protective film 140 has a surface roughness Ra of 5 nm or more so as to improve adhesion with the mold resin 60. That is, as shown in FIG. 4, in the range where the surface roughness Ra is less than 5 nm, the adhesion strength of the protective film 140 with the mold resin 60 increases with the increase in the surface roughness Ra. However, in the range where the surface roughness Ra of the protective film 140 is 5 nm or more, the adhesion strength of the protective film 140 with the mold resin 60 hardly changes. Therefore, the protective film 140 has the surface roughness Ra of 5 nm or more. Although FIG. 4 shows the results when the protective film 140 is made of polyimide, the same results are obtained when the protective film 140 is made of a nitride film or the like. In addition, the surface roughness Ra of the protective film 140 is adjusted by performing, for example, a blasting process or the like.

Further, the main face 141 of the protective film 140 on the opposite side to the semiconductor substrate 100 is formed with an uneven structure 150 defining protrusion or recess. In the present embodiment, in the protective film 140, a recessed portion 140a corresponding to the depressed portion 131 is formed in a portion located above the depressed portion 131, and the uneven structure 150 is provided by the recessed portion 140a. As shown in FIG. 2, the uneven structure 150 of the present embodiment is formed into a frame shape along the outer edge portion of the semiconductor chip 10 so as to surround the cell region 11 and the pad portions 13. The mold resin 60 is disposed so as to be received in the recessed portion 140a.

The recessed portion 140a of the present embodiment is formed by forming the protective film 140 over the depressed portion 131. Therefore, the depressed portion 131 and the gate insulating film 117 and the interlayer insulating film 19 disposed on the depressed portion 131 are formed so as to suppress the disappearance of the recessed portion 140a when the protective film 140 is formed. For example, the size of the depressed portion 131 and the thicknesses of the gate insulating film 117 and the interlayer insulating film 119 are preferably adjusted to satisfy d>2t, where d is the distance between the interlayer insulating films 119 formed on the opposing side surfaces of the depressed portion 131 and t is the thickness of the protective film 140. The recessed portion 140a has a depth of, for example, about 1 μm.

In the semiconductor device of the present embodiment, since the semiconductor chip 10 has such a configuration, when the mold resin 60 is separated from the semiconductor chip 10, it is possible to restrict the separation of the mold resin 60 from reaching the source electrode 121 and the like which are located on the inner edge side. That is, when the mold resin 60 is separated from the semiconductor chip 10, the separation is likely to occur from the outer edge portion of the interface between the protective film 140 and the mold resin 60. This separation is likely to extend along the interface between the protective film 140 and the mold resin 60. However, in the semiconductor device of the present embodiment, since the uneven structure 150 is formed, when the separation reaches the uneven structure 150, the extension direction of the separation changes. Therefore, the extension of the separation can be suppressed, and the separation can be suppressed from reaching the source electrode 121 and the like.

In this case, in the recessed portion 140a, an angle θ1 defined between the main face 141 and the side surface 142a of the recessed portion 140a is preferably 45° or more. That is, when the separation reaches the recessed portion 140a from the outer edge portion, the stress affecting the separation is dispersed into the stress in a direction in which the separation progresses as it is along the extension direction and the stress in a direction along the interface between the protective film 140 and the mold resin 60. Therefore, by setting the angle θ1 to 45° or more, the stress in the direction along the interface between the protective film 140 and the mold resin 60 is easily made larger than the stress in the direction progressing along the extension direction of the separation. As such, it becomes easy to change the propagation direction of half or more of the stress affecting the separation, and it is possible to further suppress the separation from reaching the source electrode 121 and the like.

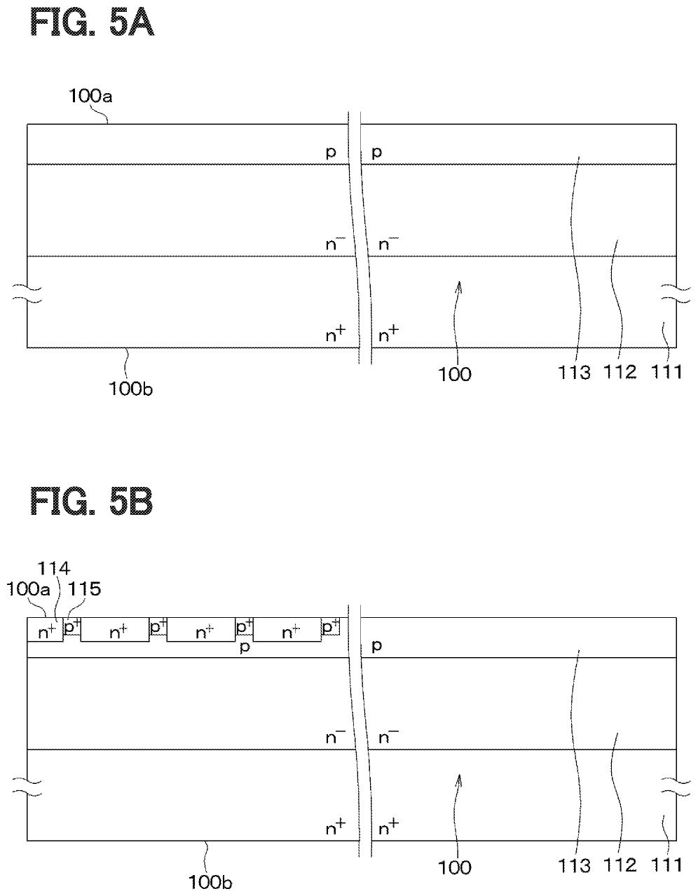

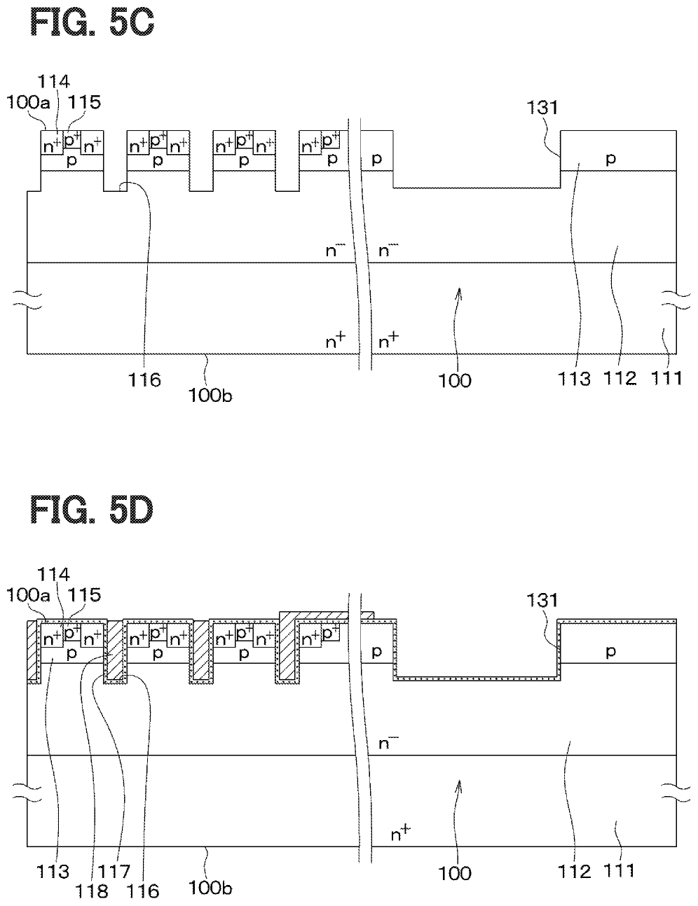

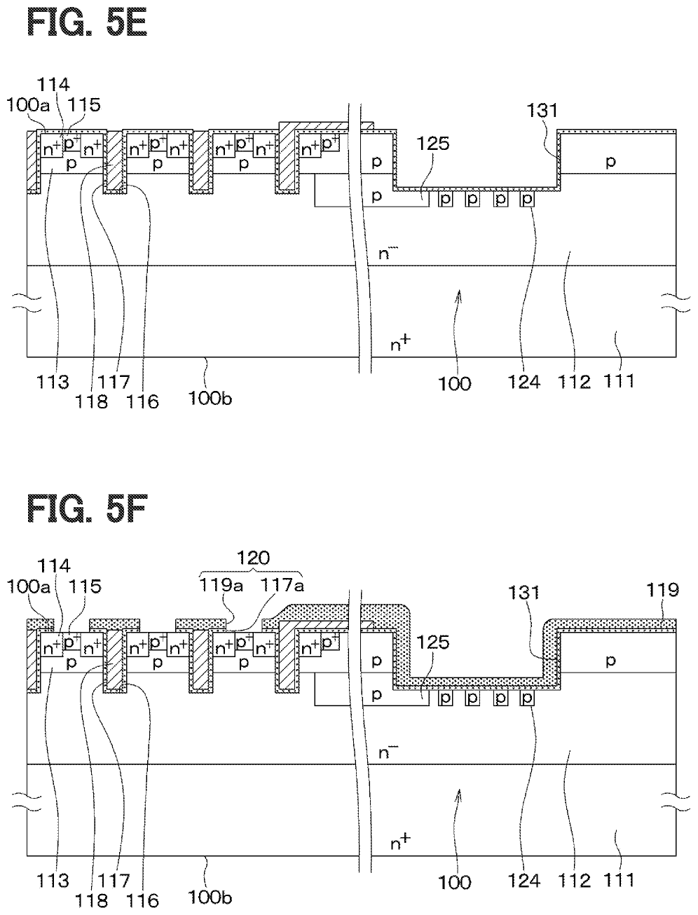

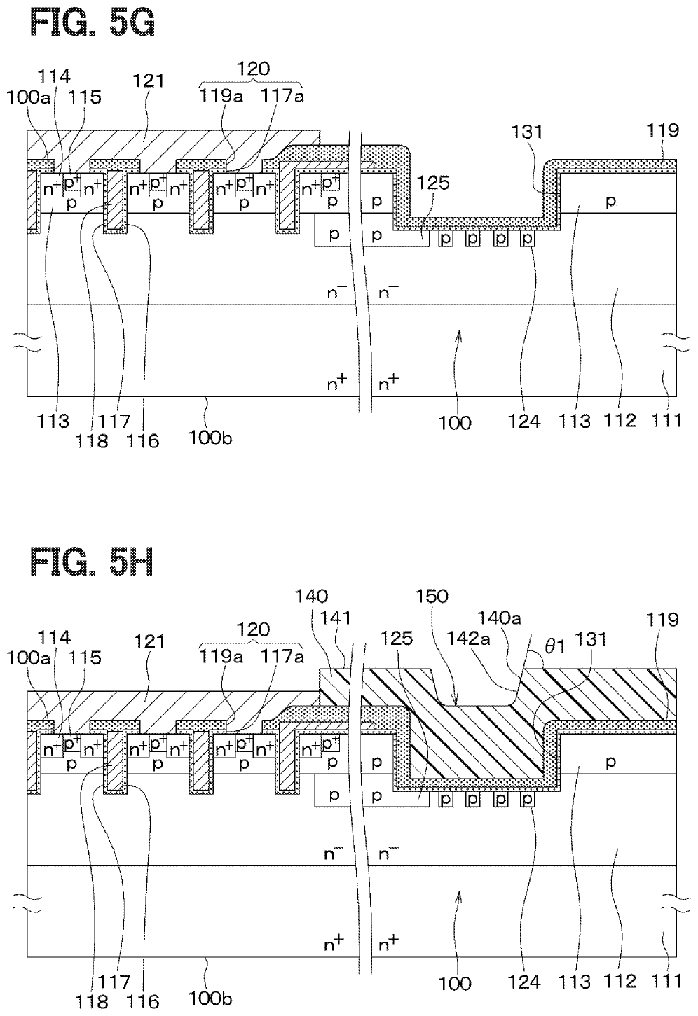

The semiconductor chip 10 and the semiconductor device according to the present embodiment have the configurations as described hereinabove. Next, a method for manufacturing the semiconductor chip 10 will be described with reference to FIGS. 5A to 5H.

First, as shown in FIG. 5A, the drift layer 112 and the base region 113 are formed on the substrate 111 to provide the semiconductor substrate 100. The drift layer 112 and the base region 113 are formed by, for example, epitaxial growth on the front surface side of the substrate 111.

Next, as shown in FIG. 5B, a mask (not illustrated) is disposed on the one surface 100a side of the semiconductor substrate 100, and ion implantation or the like is performed to sequentially form the source region 114 and the contact region 115.

Subsequently, as shown in FIG. 5C, a mask (not illustrated) is disposed on the one surface 100a side of the semiconductor substrate 100, and anisotropic etching or the like is performed to form the trench 116 and the depressed portion 131. In the present embodiment, since the trench 116 and the depressed portion 131 are formed in the same process as described above, the trench 116 and the depressed portion 131 have the same depth. Alternatively, the trench 116 and the depressed portion 131 may be formed in separate processes so that the trench 116 and the depressed portion 131 have different depths.

Thereafter, as shown in FIG. 5D, the gate insulating film 117 is formed on the wall surface of the trench 116, the one surface 100a of the semiconductor substrate 100, and the wall surface of the depressed portion 131 by thermal oxidation or the like. Then, the gate electrode 118 is formed by performing chemical vapor deposition (CVD), patterning, and the like. As described above, the gate electrode 118 is formed to extend over the connection region 12b.

Next, as shown in FIG. 5E, a mask (not illustrated) is disposed on the one surface 100a side of the semiconductor substrate 100, and ion implantation or the like is performed to form the guard ring 124 and the RESURF layer 125.

Thereafter, as shown in FIG. 5F, an interlayer insulating film 119 is formed by a CVD method or the like. Then, a mask (not shown) is disposed on the interlayer insulating film 119, and anisotropic etching or the like is performed to form the contact hole 120. Then, as shown in FIG. 5G, the source electrode 121 is formed by the CVD, patterning, and the like.

Subsequently, as shown in FIG. 5H, the protective film 140 is formed by the CVD, patterning, and the like. In this case, since the protective film 140 is formed on the depressed portion 131, the recessed portion 140a is formed in the main face 141 of the protective film 140 due to the depressed portion 131 and the uneven structure 150 is formed by the recessed portion 140a. The recessed portion 140a is preferably formed such that the angle θ1 between the main face 141 and the side surface 142a is 45° or more as described above. That is, the conditions for forming the protective film 140, the shape of the recessed portion 140a, the thicknesses of the gate insulating film 117 and the interlayer insulating film 119, and the like are preferably adjusted such that the angle θ1 is formed to be 45° or more.

Thereafter, although not particularly illustrated, the drain electrode 123 and the like are formed on the other surface 100b side of the semiconductor substrate 100. In this way, the semiconductor chip 10 described above is manufactured.

According to the present embodiment described above, the main face 141 of the protective film 140 has the surface roughness of 5 nm or more. Therefore, it is possible to suppress a decrease in the adhesion strength between the protective film 140 and the mold resin 60, and it is possible to suppress the separation of the mold resin 60 from the semiconductor chip 10.

In addition, the protective film 140 has the uneven structure 150 in the main face 141 thereof. Therefore, when the mold resin 60 is separated from the outer edge portion of the protective film 140 of the semiconductor chip 10, the extension direction of the separation can be changed by the uneven structure 150, and the stress for extending the separation can be reduced. As such, the separation can be restricted from extending to the inner edge portion of the protective film 140 of the semiconductor chip 10. Since the separation is suppressed from reaching the inner edge portion of the semiconductor chip 10, a SiC substrate or the like having a high Young's modulus can be used as the semiconductor substrate 100, and the selectivity of the semiconductor substrate 100 can be improved.

(1) In the present embodiment, the recessed portion 140a is formed in the main face of the protective film 140 by forming the depressed portion 131 in the semiconductor substrate 100. Therefore, the recessed portion 140a can be formed in the main face 141 of the protective film 140 by an easy method.

(2) In the semiconductor device as described above, when the mold resin 60 separates from the semiconductor chip 10, the mold resin 60 is likely to be separated from the outer edge portion of the semiconductor chip 10. Therefore, as in the present embodiment, by forming the uneven structure 150 so as to surround the cell region 11 and the pad portion 13, the uneven structure 150 is formed between the starting point of the separation and the source electrode 121 or the pad portion 13. As such, the uneven structure 150 can effectively restrict the separation from reaching the source electrode 121 and the pad portion 13.

(2) In the present embodiment, the angle θ1 between the surface 141 and the side surface 142a of the recessed portion 140a is 45° or more. This makes it easier to increase the stress in the direction along the interface between the protective film 140 and the mold resin 60 than the stress in the direction along the extension direction of the separation (that is, the planar direction of the semiconductor substrate 100). Therefore, it is possible to further suppress the separation from reaching the inner edge portion of the protective film 140 of the semiconductor chip 10.

### Second Embodiment

A second embodiment will be described. The present embodiment is different from the first embodiment in the configuration of the recessed portion 140a. The other configurations of the present embodiment are similar to those of the first embodiment, and therefore a description of the similar configurations will not be repeated.

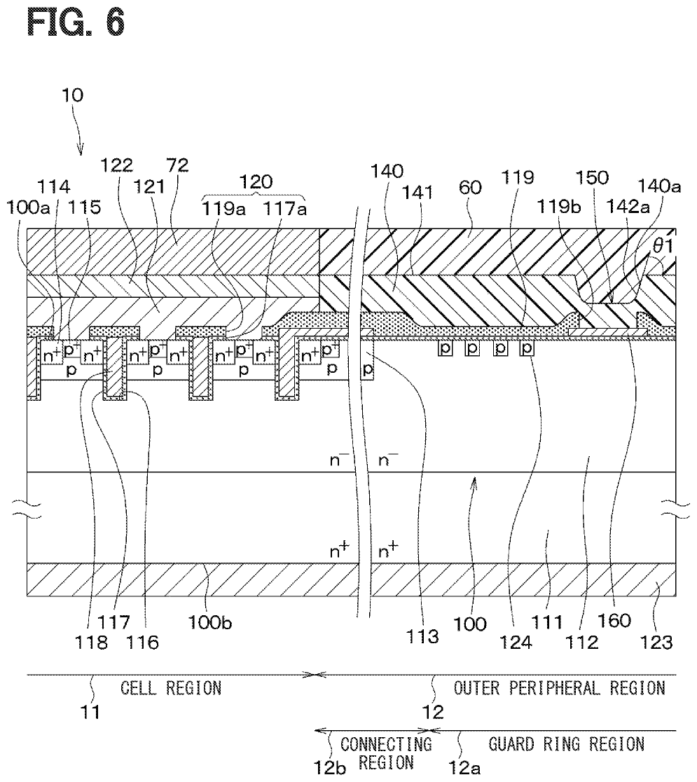

As shown in FIG. 6, in the semiconductor chip 10 of the present embodiment, the depressed portion 131 and the RESURF layer 125 are not formed in the semiconductor substrate 100. The guard ring 124 is formed on the one surface 100a side of the semiconductor substrate 100.

In the semiconductor chip 10, a stopper wiring 160 is formed on the gate insulating film 117 disposed on the one surface 100a of the semiconductor substrate 100 adjacent to the outer edge portion than the guard ring 124. The stopper wiring 160 of the present embodiment is not electrically connected to other electrodes or the like, and is arranged as a floating potential. That is, the stopper wiring 160 of the present embodiment is provided as a dummy wiring. The stopper wiring 160 of the present embodiment is made of the same material as the gate electrode 118. In the present embodiment, the stopper wiring 160 corresponds to a stopper member.

The interlayer insulating film 119 is formed with an opening 119b in a location covering the stopper wiring 160 so as to expose a part of the stopper wiring 160. The opening 119b of the present embodiment is formed simultaneously with the contact hole 120 as described later.

The protective film 140 is disposed on the interlayer insulating film 119 as described above. The protective film 140 is disposed so as to fill the opening 119b of the interlayer insulating film 119, and the recessed portion 140a depending on the opening 119b is formed on the main face 141 side.

In the present embodiment, since the opening 119b is formed closer to the outer edge portion than the guard ring 124, the recessed portion 140a is also formed closer to the outer edge portion than the guard ring 124. Therefore, in a case where the guard ring 124 has a shape in which four corners are rounded, it is preferable that the uneven structure 150 is disposed to include a portion in which the guard ring 124 is not disposed by being rounded in the stacking direction. As a result, an increase in the size of the semiconductor chip 10 can be suppressed.

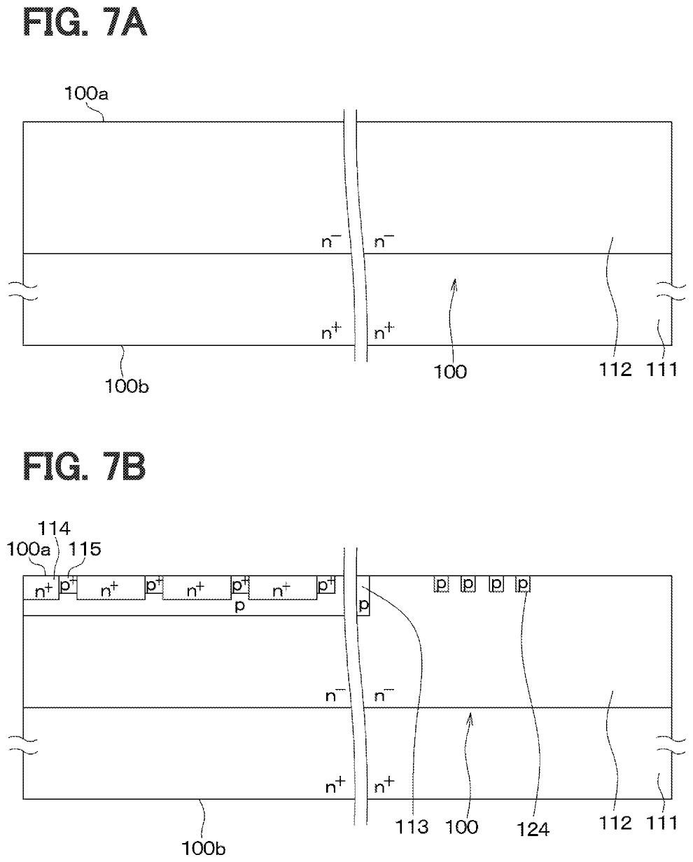

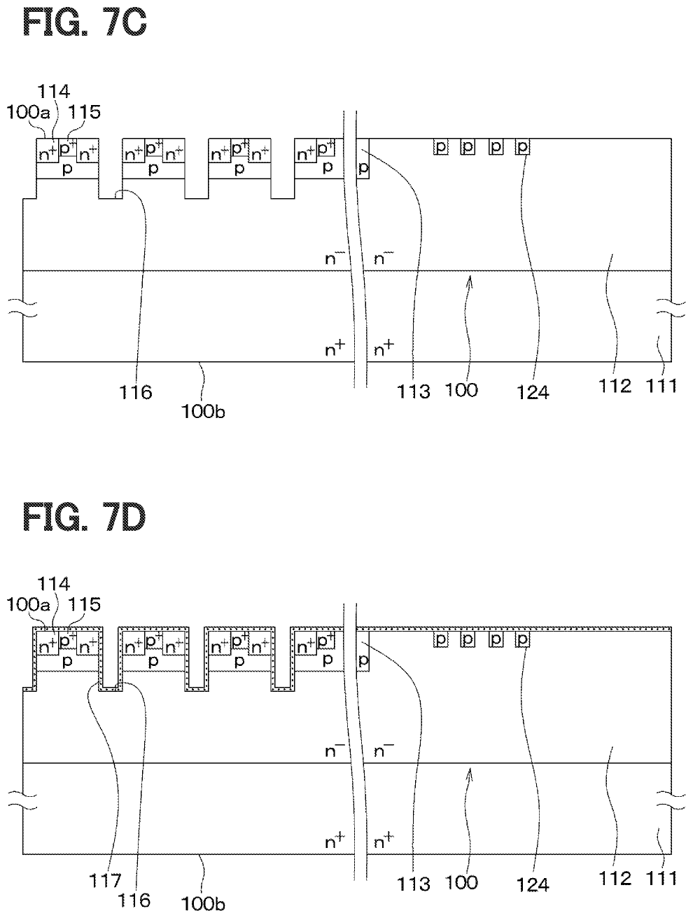

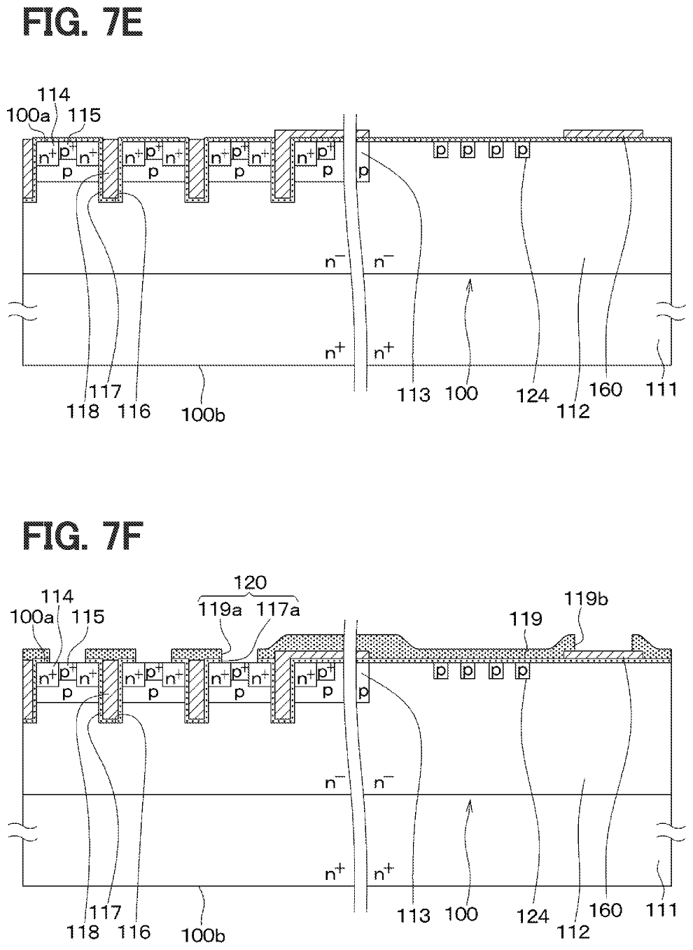

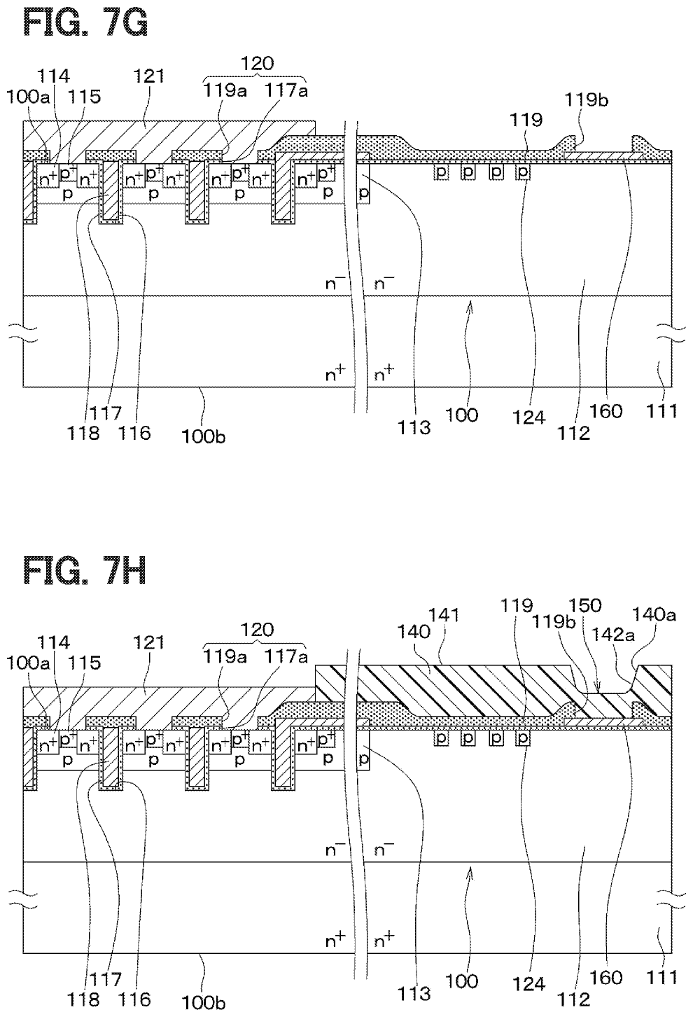

The semiconductor chip 10 of the present embodiment has the configuration as described above. Next, a method for manufacturing the semiconductor chip 10 will be described with reference to FIGS. 7A to 7H.

In the present embodiment, as shown in FIG. 7A, the semiconductor substrate 100 having the drift layer 112 is prepared. Then, as shown in FIG. 7B, the base region 113, the source region 114, the contact region 115, and the guard ring 124 are sequentially formed by arranging a mask (not shown) and performing ion implantation or the like.

Subsequently, as shown in FIG. 7C, the trench 116 is formed by performing a process similar to the process shown in FIG. 5C. However, in the present embodiment, the depressed portion 131 is not formed.

Next, as shown in FIGS. 7D and 7E, the gate insulating film 117 and the gate electrode 118 are sequentially formed by performing the similar process to the process shown in FIG. 5D. In the present embodiment, as shown in FIG. 7E, when the gate electrode 118 is formed by patterning, the stopper wiring 160 is formed at the same time. Therefore, the stopper wiring 160 of the present embodiment is made of the same material as the gate electrode 118.

Then, as shown in FIG. 7F, the interlayer insulating film 119 is formed in the interlayer insulating film 119 by performing the similar process to the process shown in FIG. 5F and the contact hole 120 is also formed. In the present embodiment, the opening 119b for exposing the stopper wiring 160 is also formed at the same time. At this time, the stopper wiring 160 can restrict the semiconductor substrate 100 from being etched by the etching for exposing the opening 119b. That is, the stopper wiring 160 of the present embodiment also functions as an etching stopper.

Next, as shown in FIG. 7G, the source electrode 121 is formed by performing the similar process to the process shown in FIG. 5G. Thereafter, as shown in FIG. 7H, the protective film 140 is formed by performing the similar process to the process shown in FIG. 5H. At this time, since the protective film 140 is formed in the opening 119b, the recessed portion 140a caused by the opening 119b is formed in the main face 141 of the protective film 140.

Thereafter, although not particularly shown, the drain electrode 123 and the like are formed on the other surface 100b side of the semiconductor substrate 100. In this way, the semiconductor chip 10 described above is produced.

According to the present embodiment described above, since the protective film 140 has the surface roughness of 5 nm or more and has the uneven structure 150 in the main face 141, the similar effects to those of the first embodiment can be obtained.

(1) In the present embodiment, the recessed portion 140a is formed in the main face 141 of the protective film 140 by forming the opening 119b in the interlayer insulating film 119. Even when the recessed portion 140a is formed in the main face 141 of the protective film 140 in this manner, the recessed portion 140a can be formed in the main face 141 of the protective film 140 by an easy method. In the present embodiment, the stopper wiring 160 is formed so as to be exposed from the opening 119b. Therefore, when the opening 119b is formed in the interlayer insulating film 119, the semiconductor substrate 100 can be suppressed from being etched. The stopper wiring 160 may be made of a material different from that of the gate electrode 118, or may be made of an insulating material.

(2) In the present embodiment, the stopper wiring 160 is made of the same material as that of the gate electrode 118, and is formed simultaneously with the forming of the gate electrode 118. The opening 119b of the interlayer insulating film 119 is formed simultaneously with the forming of the contact hole 120. Therefore, the recessed portion 140a can be formed in the main face 141 of the protective film 140 while suppressing an increase in the number of manufacturing processes.

(3) In the present embodiment, the uneven structure 150 is formed on the outer edge side than the guard ring 124. Therefore, when the mold resin 60 is separated from the outer edge portion of the semiconductor chip 10, the extension of the separation can be suppressed at an early stage.

### Third Embodiment

A third embodiment will be described. The present embodiment is different from the second embodiment in the configuration of the recessed portion 140a. The other configurations of the present embodiment are similar to those of the second embodiment, and therefore a description of the similar configurations will not be repeated.

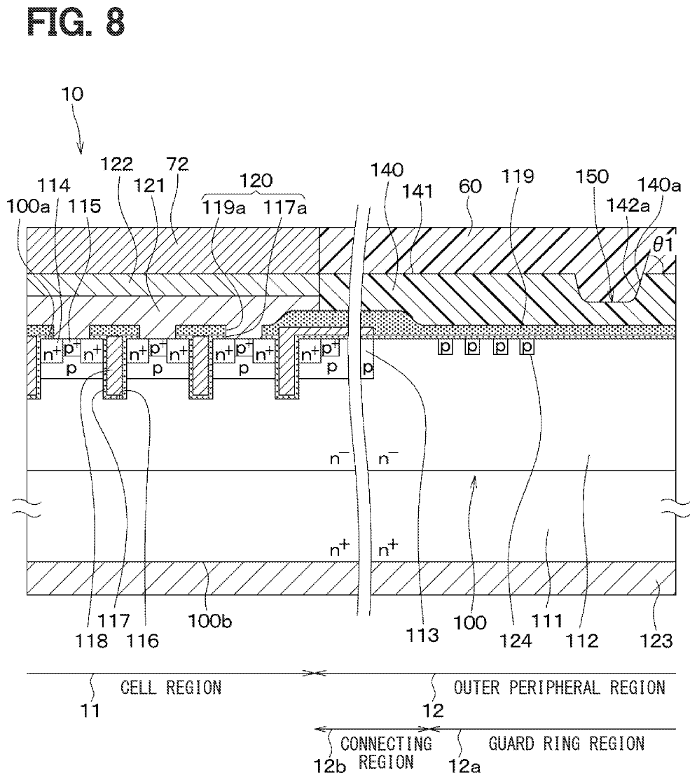

In the semiconductor chip 10 of the present embodiment, as shown in FIG. 8, the recessed portion 140a is formed in the main face 141 of the protective film 140, but the opening 119b is not formed in the interlayer insulating film 119. In addition, the stopper wiring 160 in the second embodiment is also not disposed.

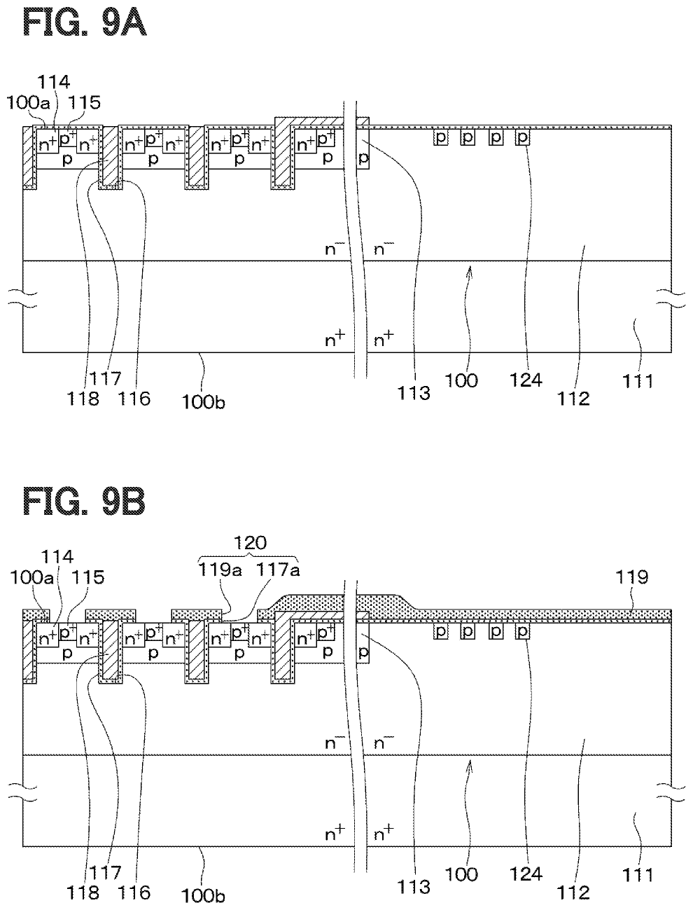

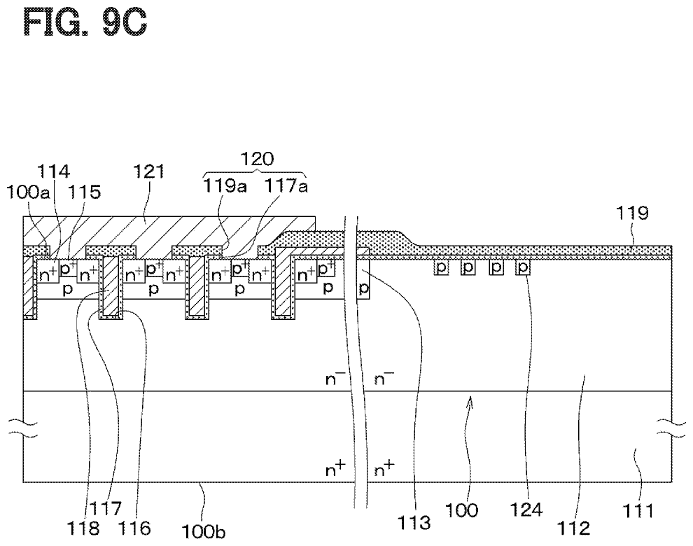

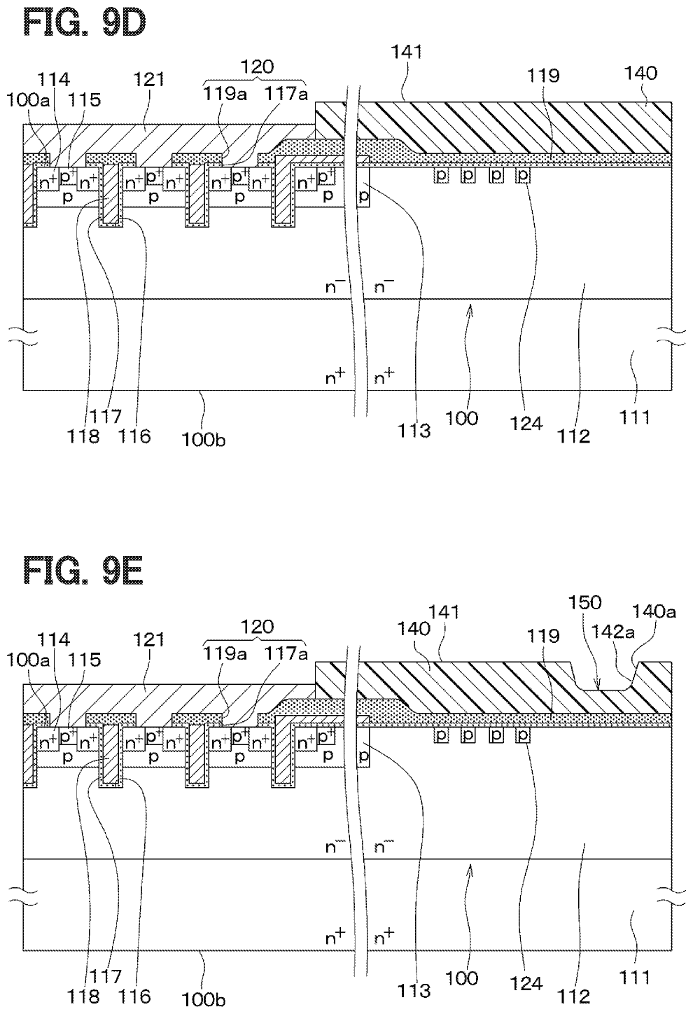

The semiconductor chip 10 of the present embodiment has the configuration described above. Next, a method for manufacturing the semiconductor chip 10 will be described with reference to FIGS. 9A to 9E.

In the present embodiment, after the processes shown in FIGS. 7A to 7C are performed, as shown in FIG. 9A, a process similar to the process shown in FIG. 5D is performed to form the gate insulating film 117 and the gate electrode 118. However, in the present embodiment, the gate electrode 118 is formed so as not to form the stopper wiring 160.

Next, as shown in FIG. 9B, the interlayer insulating film 119 is formed and the contact hole 120 is formed in the interlayer insulating film 119 by performing the similar process to the process shown in FIG. 7F. Subsequently, as shown in FIG. 9C, the similar process to the process shown in FIG. 7G is performed to form source electrode 121.

Then, as shown in FIG. 9D, the protective film 140 is formed by performing the similar process to the process shown in FIG. 7H. In the present embodiment, since the opening 119b is not formed, the main face 141 is substantially planar after the process shown in FIG. 9D is performed.

Next, as shown in FIG. 9E, the protective film 140 is etched using a photoresist (not shown) as a mask so as to form the recessed portion 140a in the protective film 140. Thereafter, although not particularly shown, the drain electrode 123 and the like are formed on the other surface 100b side of the semiconductor substrate 100. In this way, the semiconductor chip 10 is produced.

According to the present embodiment described above, since the protective film 140 has the surface roughness of 5 nm or more and has the uneven structure 150 in the main face 141, the similar effects to those of the first embodiment can be obtained.

(1) In the present embodiment, the recessed portion 140a is formed on the main face 141 of the protective film 140 by etching. Therefore, the shape of the recessed portion 140a can be easily adjusted, and the angle 01 formed by the main face 141 and the side surface 142a can be easily adjusted in detail.

### Fourth Embodiment

A fourth embodiment will be described. The present embodiment is different from the third embodiment in that a protrusion is formed on the main face 141 of the protective film 140. The other configurations of the present embodiment are similar to those of the third embodiment, and therefore a description of the similar configurations will not be repeated.

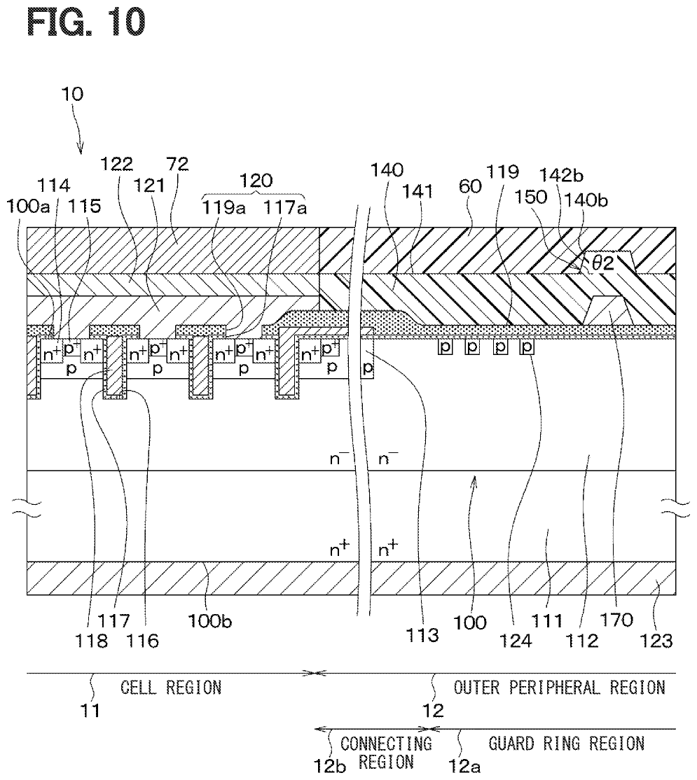

In the semiconductor chip 10 of the present embodiment, as shown in FIG. 10, a protrusion wiring 170 for the protrusion is formed on the interlayer insulating film 119 on the outer edge side than the guard ring 124. The protrusion wiring 170 is not electrically connected to other electrodes or the like, and has a floating potential. That is, the protrusion wiring 170 of the present embodiment is provided as a dummy wiring. The protrusion wiring 170 of the present embodiment is made of the same material as the source electrode 121. In the present embodiment, the protrusion wiring 170 corresponds to a protrusion member.

The protective film 140 is disposed on the interlayer insulating film 119 as described above, and is disposed so as to also cover the protrusion wiring 170. Therefore, a protruded portion 140b caused by the protrusion wiring 170 is formed on the main face 141 side of the protective film 140. As in the first embodiment, the angle 02 between the side surface 142b of the protruded portion 140b and the main face 141 is preferably 45° or more. In the present embodiment, the uneven structure 150 is configured by the protruded portion 140b.

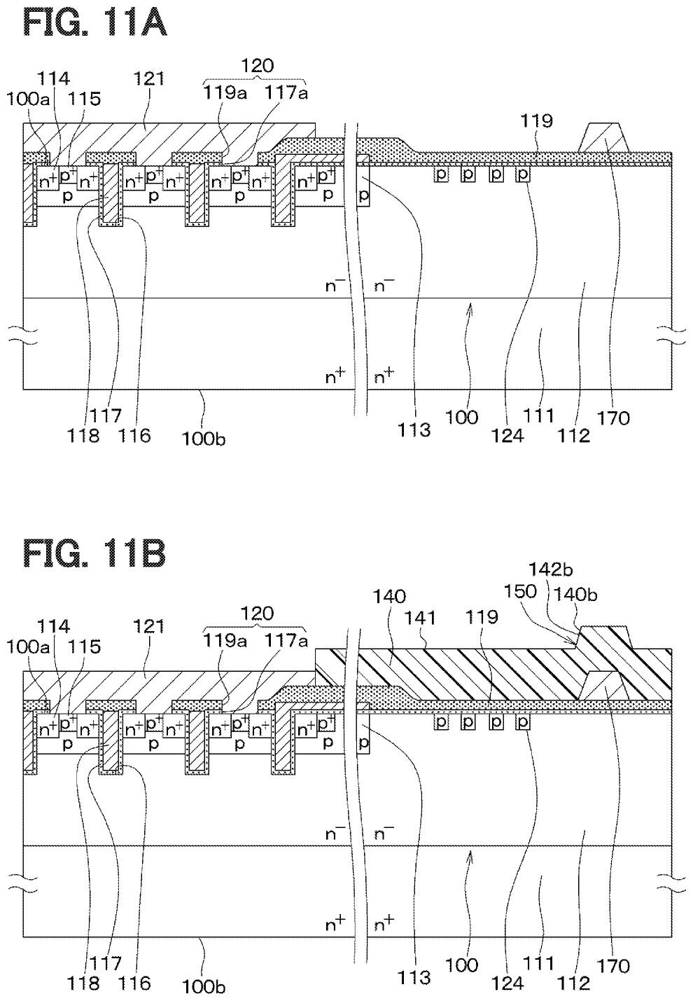

The semiconductor chip 10 of the present embodiment has the configuration described above. Next, a method for manufacturing the semiconductor chip 10 will be described with reference to FIGS. 11A and 11B.

In the present embodiment, after the processes shown in FIGS. 9A and 9B are performed, as shown in FIG. 11A, the similar process to the process shown in FIG. 9C is performed to form the source electrode 121. In the present embodiment, as shown in FIG. 11A, when the source electrode 121 is formed by patterning, the protrusion wiring 170 is left. Therefore, the protrusion wiring 170 of the present embodiment is made of the same material as the source electrode 121.

Next, as shown in FIG. 11B, the protective film 140 is formed by performing the similar process to the process shown in FIG. 9D. At this time, since the protective film 140 is formed on the protrusion wiring 170, the protruded portion 140b caused by the protrusion wiring 170 is formed on the main face 141 of the protective film 140. Thereafter, although not particularly shown, the drain electrode 123 and the like are formed on the other surface 100b side of the semiconductor substrate 100. In this way, the semiconductor chip 10 is produced.

According to the present embodiment described above, since the protective film 140 has the surface roughness of 5 nm or more, and has the uneven structure 150 on the main face 141, the similar effects to those of the first embodiment can be obtained. In the present embodiment, the direction of stress of the separation is changed by the protruded portion 140b.

(1) In the present embodiment, the protruded portion 140b is formed on the main face 141 of the protective film 140 by forming the protrusion wiring 170 on the interlayer insulating film 119. Even when the protruded portion 140b is formed on the main face 141 of the protective film 140 in this manner, the protruded portion 140b can be formed on the main face 141 of the protective film 140 by an easy method.

(2) In the present embodiment, the protruded wiring 170 is made of the same material as the source electrode 121, and is formed at the same time when the source electrode 121 is formed. Therefore, it is possible to form the protruded portion 140b on the main face 141 of the protective film 140 while suppressing an increase in the number of manufacturing processes.

### Modification of Fourth Embodiment

The fourth embodiment described above can be modified as follows. In the configuration of the fourth embodiment, the protrusion wiring 170 may not be made of the same material as the source electrode 121, and may be made of the same material as other wirings. For example, when the protrusion wiring 170 has an EQR structure, the protrusion wiring 170 may be formed of the same material as the wiring forming the EQR structure. In addition, the protrusion wiring 170 (that is, the protrusion member) may be formed of a material different from each wiring, or may be formed of an insulating material.

### Fifth Embodiment

A fifth embodiment will be described. The present embodiment is different from the fourth embodiment in the configuration of the protruded portion 140b. The other configurations of the present embodiment are similar to those of the fourth embodiment, and therefore a description of the similar configurations will not be repeated.

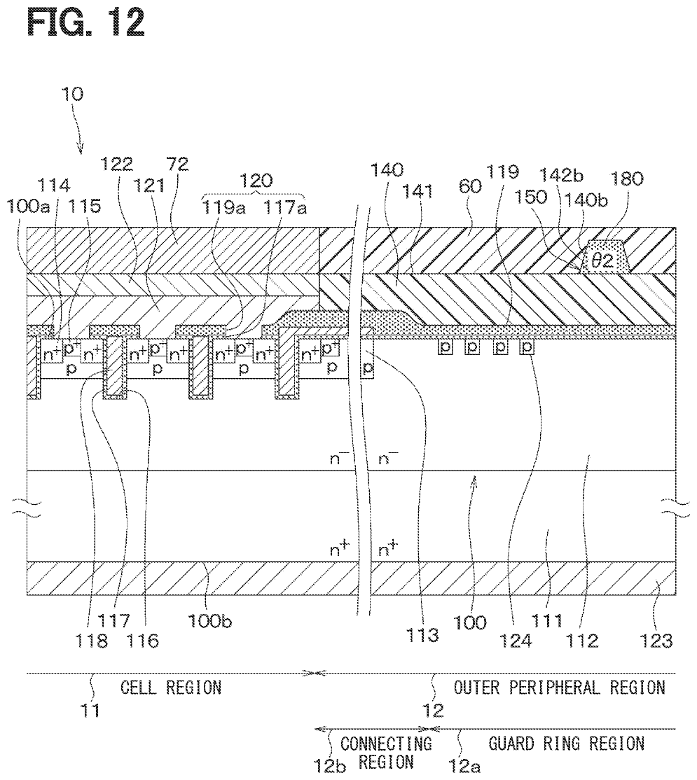

In the semiconductor chip 10 of the present embodiment, as shown in FIG. 12, the protruded portion 140b is formed on the main face 141 of the protective film 140, but the protrusion wiring 170 is not formed. In addition, the protruded portion 140b of the present embodiment is configured by arranging a projection 180 on the main face 141 of the protective film 140.

For example, after the protective film 140 is formed, the projection 180 is formed by applying a material in a shape of projection using a dispenser, a 3D printer, or the like and curing the material. The projection 180 may be made of the same material as the protective film 140 or may be made of a different material.

According to the present embodiment described above, since the protective film 140 has the surface roughness of 5 nm or more and has the uneven structure 150 on the main face 141, the similar effects to those of the fourth embodiment can be obtained.

### Sixth Embodiment

A sixth embodiment will be described. The present embodiment is different from the first embodiment in the formation location where the uneven structure 150 is formed. The other configurations of the present embodiment are similar to those of the first embodiment, and therefore a description of the similar configurations will not be repeated.

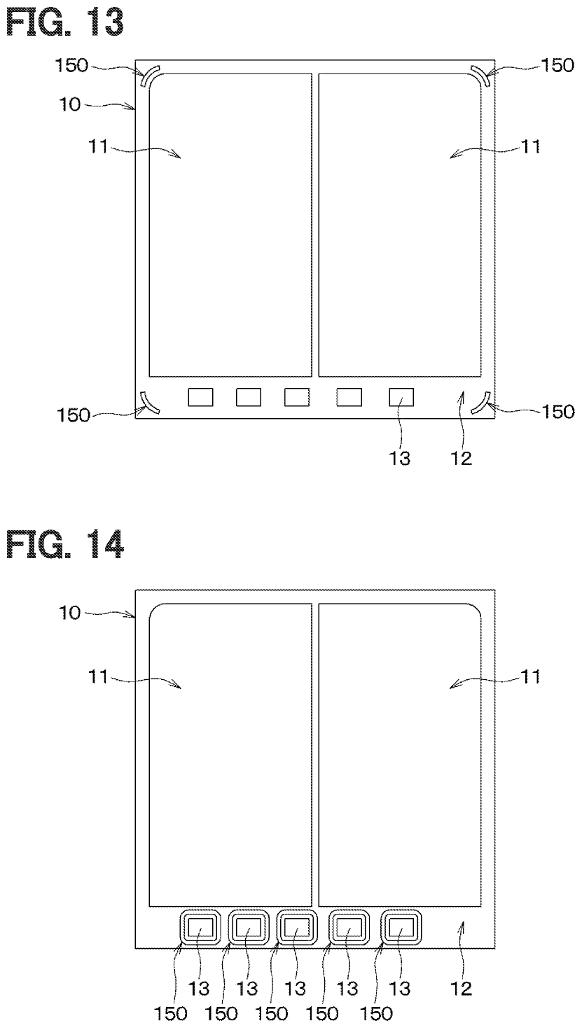

In the semiconductor chip 10 of the present embodiment, as shown in FIG. 13, the uneven structure 150 is divided into a plurality of parts and formed in the vicinity of each corner of the semiconductor chip 10. Specifically, the uneven structure 150 is disposed between the corner portion of the semiconductor chip 10 and the cell region 11 or the pad portion 13 in the outer peripheral region 12.

The formation location of the uneven structure 150 of the present embodiment can also be applied to the second to fifth embodiments described above. In a case where the guard ring 124 has a shape in which the four corners are rounded, the uneven structure 150 is preferably disposed to include a portion in which the guard ring 124 is not disposed by being rounded in the stacking direction. As a result, an increase in the size of the semiconductor chip 10 can be suppressed.

According to the present embodiment described above, since the protective film 140 has the surface roughness of 5 nm or more and has the uneven structure 150 on the main face 141, the similar effects to those of the first embodiment can be obtained.

(1) In the semiconductor device as described above, when the mold resin 60 is separated from the semiconductor chip 10, the mold resin 60 is easily separated from the outer edge portion of the semiconductor chip 10. The mold resin 60 is easily separated particularly from the corner portion of the semiconductor chip 10. Therefore, by arranging the uneven structure 150 between the corner portion of the semiconductor chip 10 and the cell region 11 or the pad portion 13 as in the present embodiment, the uneven structure 150 can effectively suppress the separation from reaching the source electrode 121 and the pad portion 13.

### Seventh Embodiment

A seventh embodiment will be described. The present embodiment is different from the first embodiment in the formation location of the uneven structure 150. The other configurations of the present embodiment are similar to those of the first embodiment, and therefore a description of the similar configurations will not be repeated.

First, in the semiconductor chip 10 as described above, the plane area of the source electrode 121 is sufficiently larger than that of the pad portion 13. Therefore, when the mold resin 60 is separated from the semiconductor chip 10 and the separation reaches the pad portion 13, the influence is larger than that when the separation reaches the source electrode 121.

Therefore, in the semiconductor chip 10 of the present embodiment, as shown in FIG. 14, the uneven structure 150 is formed so as to surround each pad portion 13.

According to the present embodiment described above, since the protective film 140 has the surface roughness of 5 nm or more and has the uneven structure 150 on the main face 141, the similar effects to those of the first embodiment can be obtained.

(1) In the present embodiment, the uneven structure 150 is formed so as to surround the pad portion 13. Therefore, it is possible to restrict the separation from reaching at least the pad portion 13, which is more likely to be affected by the separation than the source electrode 121. In addition, since a space around the pad portion 13 is widened due to a restriction of a wire bonding apparatus or the like, it is possible to suppress an increase in size of the semiconductor chip 10 by disposing the uneven structure 150 in the space.

### Eighth Embodiment

An eighth embodiment will be described. The present embodiment is different from the seventh embodiment in the formation location of the uneven structure 150. The other configurations of the present embodiment are similar to those of the seventh embodiment, and therefore a description of the similar configurations will not be repeated.

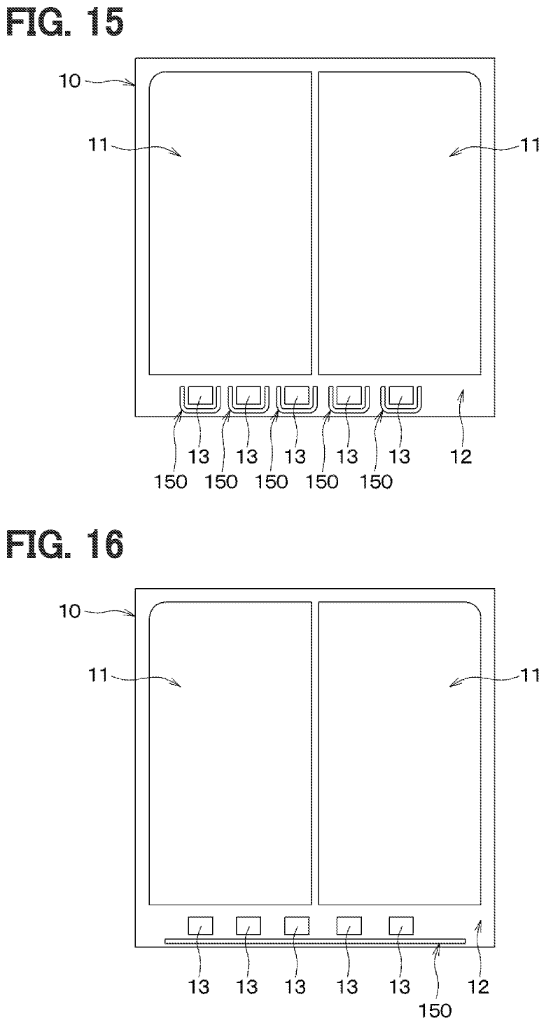

First, in the semiconductor chip 10 as described above, a wiring connecting the pad portion 13 and the cell region 11 is formed, but there is a case where it is difficult to form the uneven structure 150 so as to surround the pad portion 13 due to the wiring. Therefore, in the semiconductor chip 10 of the present embodiment, as shown in FIG. 15, the uneven structure 150 is formed so as to substantially surround the pad portion 13 instead of completely surrounding the pad portion 13. In the present embodiment, the uneven structure 150 is formed in a substantially U shape so as not to close a portion of the pad portion 13 on the cell region 11 side. In other words, the uneven structure 150 is formed so as not to intersect a virtual line connecting the pad portion 13 and the cell region 11. However, when the mold resin 60 is separated as described above, the separation is likely to occur from the corner portion of the semiconductor chip 10. Therefore, the uneven structure 150 is preferably formed at least between the pad portion 13 and the corner portion of the semiconductor chip 10.

According to the present embodiment described above, since the protective film 140 has the surface roughness of 5 nm or more and has the uneven structure 150 on the main face 141, the similar effects to those of the first embodiment can be obtained.

(1) Even when the pad portion 13 is not completely surrounded by the uneven structure 150 as in the present embodiment, the uneven structure 150 can suppress the separation from reaching the pad portion 13, and thus the similar effects to those of the seventh embodiment can be obtained. In addition, since the pad portion 13 is not completely surrounded by the uneven structure 150, the connection wiring can be easily disposed through the non-surrounded portion, and the degree of freedom in design can be improved.

### Ninth Embodiment

A ninth embodiment will be described. The present embodiment is different from the eighth embodiment in the formation location of the uneven structure 150. The other configurations of the present embodiment are similar to those of the eighth embodiment, and therefore a description of the similar configurations will not be repeated.

In the semiconductor chip 10 of the present embodiment, as shown in FIG. 16, the uneven structure 150 is disposed between the pad portion 13 and the outer edge portion of the semiconductor chip 10.

According to the present embodiment described above, since the protective film 140 has the surface roughness of 5 nm or more and has the uneven structure 150 on the main face 141, the similar effects to those of the first embodiment can be obtained.

(1) Even when the uneven structure 150 is formed between the pad portion 13 and the outer edge end portion of the semiconductor chip 10 as in the present embodiment, the uneven structure 150 can suppress the separation from reaching the pad portion 13, and thus the similar effects to those of the eighth embodiment can be obtained.

### Other Embodiments

Although the present disclosure has been described in accordance with the embodiments, it is understood that the present disclosure is not limited to such embodiments or structures. The present disclosure encompasses various modifications and variations within the scope of equivalents. In addition, various combinations and configurations, as well as other combinations and configurations that include only one element, more, or less, fall within the scope and spirit of the present disclosure.

For example, in each of the embodiments described above, the semiconductor element formed in the semiconductor chip 10 can be appropriately changed. Specifically, the semiconductor element may be a MOSFET having a trench gate structure of a p-channel type in which the conductivity type of each component is inverted with respect to an n-channel type. Further, the semiconductor element may have a configuration in which an IGBT having a similar structure is formed in addition to the MOSFET. In the case of IGBT, the n⁺-type substrate 11 in the first embodiment is modified to the p⁺-type collector layer. Other than that, IGBT is similar to the MOSFET as described in the first embodiment. Further, the gate structure may be a planar gate structure instead of the trench gate structure.

Further, in each of the embodiments described above, the uneven structure 150 may be formed so as to reach the outer edge portion of the semiconductor chip 10 in a portion where there is no restriction on the semiconductor chip 10. For example, in the first embodiment, the recessed portion 140a formed in the main face 141 of the protective film 140 may be formed so as to reach the outer edge portion of the semiconductor chip 10 and may not have opposing side surfaces.

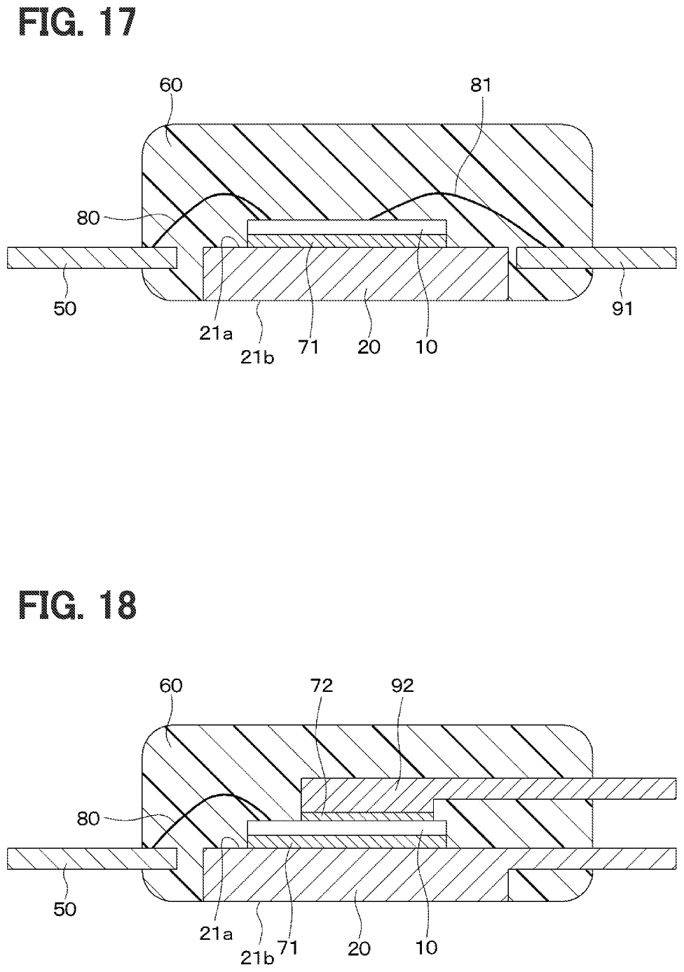

In each of the embodiments described above, the semiconductor device including the first lead frame 20 and the second lead frame 40 in which the other surface 21b of the first lead frame 20 and the other surface 41b of the second lead frame 40 are exposed from the mold resin 60 has been described as an example. However, the configuration of the semiconductor device is not limited thereto. For example, the semiconductor device may have a single-sided heat dissipation structure in which heat is dissipated only from the drain electrode 123 side of the semiconductor chip 10. In the case of the one-side heat dissipation structure, as shown in FIG. 17, a connection terminal portion 91 may be disposed in the vicinity of the semiconductor chip 10 instead of the second lead frame 40, and the source electrode 121 may be connected to the connection terminal portion 91 via a wire 81. Further, as shown in FIG. 18, a lead-out terminal portion 92 may be disposed on the source electrode 121 via a bonding member 72, and a part of the lead-out terminal portion 92 may be exposed from the mold resin 60. Although not particularly illustrated, the semiconductor device may have a configuration in which the mold resin 60 is disposed to cover the other surface 21b of the first lead frame 20 and the other surface 41b of the second lead frame 40.

The embodiments described above can be appropriately combined. For example, in the first embodiment, as in the second to fifth embodiments, the uneven structure 150 may be formed closer to the outer edge portion than the guard ring 124 when viewed along the stacking direction. In the second to fifth embodiments, the uneven structure 150 may be formed on the guard ring 124 as in the first embodiment. The protective film 140 may include at least one of the recessed portions 140a of the first to third embodiments and at least one of the protruded portions 140b of the fourth and fifth embodiments. That is, the uneven structure 150 formed in the protective film 140 may include a plurality of different recessed portions 140a and protruded portions 140b. The formation location of the uneven structure 150 in the sixth to ninth embodiments can be appropriately applied to the first to fifth embodiments.

What is claimed is:

1. A semiconductor device comprising:
a support member having a surface;
a semiconductor chip including a semiconductor substrate, the semiconductor substrate having a first surface and a second surface opposite to the first surface and formed with a semiconductor element, the semiconductor chip being disposed on the support member such that the second surface of the semiconductor substrate faces the support member; and
a mold resin sealing the support member and the semiconductor chip, wherein
the semiconductor chip has a cell region in which the semiconductor element is disposed and an outer peripheral region surrounding the cell region,
the semiconductor chip has a protective film disposed in the outer peripheral region on a side adjacent to the first surface of the semiconductor substrate,
a surface of the protective film opposite to the semiconductor substrate has a surface roughness of 5 nm or more, and includes an uneven structure,
the uneven structure includes a recessed portion,
the semiconductor chip includes a stopper member disposed in the outer peripheral region on the first surface of the semiconductor substrate, and an interlayer insulating film covering the stopper member,
the interlayer insulating film is formed with an opening from which the stopper member is exposed,
the protective film is disposed to cover the interlayer insulating film and received in the opening of the interlayer insulating film, and
the recessed portion of the uneven structure of the surface of the protective film is provided by a portion of the protective film received in the opening of the interlayer insulating film.

2. The semiconductor device according to claim 1, wherein
the semiconductor element includes a gate electrode, and
the stopper member is provided by a same material as the gate electrode.

3. The semiconductor device according to claim 1, wherein
the uneven structure of the surface of the protective film includes a protrusion.

4. The semiconductor device according to claim 1, wherein
the semiconductor chip includes
an electrode disposed in the cell region on the side adjacent to the first surface of the semiconductor substrate and electrically connected to the semiconductor element, and
a pad portion disposed in the outer peripheral region and electrically connected to the semiconductor element, the pad portion having an area smaller than that of the electrode, and
the uneven structure is disposed between the pad portion and an outer edge portion of the semiconductor chip.

5. The semiconductor device according to claim 1, wherein
an angle defined between the surface of the protective film and a side surface of the recessed portion of the uneven structure is 45 degrees or more.

6. The semiconductor device according to claim 1, wherein
the semiconductor chip is formed with a guard ring in the outer peripheral region, the guard ring surrounding the cell region, and
the uneven structure is disposed between the guard ring and an outer edge portion of the semiconductor chip.

7. The semiconductor device according to claim 1, wherein
the semiconductor chip has a shape including a corner portion as a planar shape, and
the uneven structure is disposed between the cell region and the corner portion of the semiconductor chip.

8. The semiconductor device according to claim 1, wherein
the semiconductor chip includes
an electrode disposed in the cell region on the side adjacent to the first surface of the semiconductor substrate and electrically connected to the semiconductor element, and
a pad portion disposed in the outer peripheral region and electrically connected to the semiconductor element, the pad portion having an area smaller than that of the electrode, and
the uneven structure is disposed to surround the pad portion.

9. A semiconductor device comprising:
a support member having a surface;
a semiconductor chip including a semiconductor substrate, the semiconductor substrate having a first surface and a second surface opposite to the first surface and formed with a semiconductor element, the semiconductor chip being disposed on the support member such that the second surface of the semiconductor substrate faces the support member; and
a mold resin sealing the support member and the semiconductor chip, wherein
the semiconductor chip has a cell region in which the semiconductor element is disposed and an outer peripheral region surrounding the cell region,
the semiconductor chip has a protective film disposed in the outer peripheral region on a side adjacent to the first surface of the semiconductor substrate,
a surface of the protective film opposite to the semiconductor substrate has a surface roughness of 5 nm or more, and includes an uneven structure, and
the uneven structure includes a protrusion.

10. The semiconductor device according to claim 9, wherein
the semiconductor chip includes a protrusion member in the outer peripheral region on the first surface of the semiconductor substrate, and
the protective film is disposed to cover the protrusion member so as to provide the protrusion.

11. The semiconductor device according to claim 9, wherein
the semiconductor chip includes an electrode in the cell region on the first surface of the semiconductor substrate,
the electrode is electrically connected to the semiconductor element, and
the protrusion member is made of a same material as the electrode.

12. The semiconductor device according to claim 9, wherein
an angle defined between the surface of the protective film and a side surface of the protrusion of the uneven structure is 45 degrees or more.

13. The semiconductor device according to claim 9, wherein
the semiconductor chip is formed with a guard ring in the outer peripheral region, the guard ring surrounding the cell region, and
the uneven structure is disposed between the guard ring and an outer edge portion of the semiconductor chip.

14. The semiconductor device according to claim 9, wherein
the semiconductor chip has a shape including a corner portion as a planar shape, and
the uneven structure is disposed between the cell region and the corner portion of the semiconductor chip.

15. The semiconductor device according to claim 9, wherein
the semiconductor chip includes
an electrode disposed in the cell region on the side adjacent to the first surface of the semiconductor substrate and electrically connected to the semiconductor element, and
a pad portion disposed in the outer peripheral region and electrically connected to the semiconductor element, the pad portion having an area smaller than that of the electrode, and the uneven structure is disposed to surround the pad portion.

16. A semiconductor device comprising:
a support member having a surface;
a semiconductor chip including a semiconductor substrate, the semiconductor substrate having a first surface and a second surface opposite to the first surface and formed with a semiconductor element, the semiconductor chip being disposed on the support member such that the second surface of the semiconductor substrate faces the support member; and
a mold resin sealing the support member and the semiconductor chip, wherein
the semiconductor chip has a cell region in which the semiconductor element is disposed and an outer peripheral region surrounding the cell region,
the semiconductor chip has a protective film disposed in the outer peripheral region on a side adjacent to the first surface of the semiconductor substrate,
a surface of the protective film opposite to the semiconductor substrate has a surface roughness of 5 nm or more, and includes an uneven structure,
the semiconductor chip includes
an electrode disposed in the cell region on the side adjacent to the first surface of the semiconductor substrate and electrically connected to the semiconductor element, and
a pad portion disposed in the outer peripheral region and electrically connected to the semiconductor element, the pad portion having an area smaller than that of the electrode, and
the uneven structure is disposed between the pad portion and an outer edge portion of the semiconductor chip.

17. The semiconductor device according to claim 16, wherein
the uneven structure includes a recessed portion provided on the surface of the protective film.

18. The semiconductor device according to claim 17, wherein
the semiconductor substrate is formed with a depressed portion depressed from the first surface in the outer peripheral region, and
the recessed portion on the surface of the protective film is provided by a portion of the protective film revised in the depressed portion.

19. The semiconductor device according to claim 16, wherein
an angle defined between the surface of the protective film and a side surface of the uneven structure is 45 degrees or more.

20. The semiconductor device according to claim 16, wherein
the semiconductor chip is formed with a guard ring in the outer peripheral region, the guard ring surrounding the cell region, and
the uneven structure is disposed between the guard ring and an outer edge portion of the semiconductor chip.
